(19) United States
(12) Patent Application Publication
(10) Pub. No.: US 2026/0341337 A1
(43) Pub. Date: Oct. 29, 2026

(54) SEMICONDUCTOR DEVICE AND METHOD OF OPERATING SEMICONDUCTOR DEVICE

(71) Applicant: SK hynix Inc., Gyeonggi-do (KR)

(72) Inventors: Kyung Mook KIM, Gyeonggi-do (KR); Bo Yeun KIM, Gyeonggi-do (KR); Hong Kyeom KIM, Gyeonggi-do (KR)

(21) Appl. No.: 19/294,286

(22) Filed: Aug. 8, 2025

(30) Foreign Application Priority Data
Apr. 23, 2025 (KR) 10-2025-0053173

(51) Int. Cl. G11C 11/408; G11C 11/406

(52) U.S. Cl. CPC G11C 11/4087; G11C 11/406

(57) ABSTRACT

A semiconductor device includes a refresh control circuit configured to generate a refresh address during a refresh operation, and a row decoder configured to decode a row address during a normal operation and decode the refresh address, which has the number of bits different from the number of bits of the row address, during the refresh operation.

### CROSS-REFERENCE TO RELATED APPLICATION

This application claims priority under 35 U.S.C. §119(a) to Korean Patent Application No. 10-2025-0053173, filed on Apr. 23, 2025, the entire content of which is incorporated herein by reference.

### BACKGROUND

### 1. Technical Field

Embodiments of the present disclosure relate to an integrated circuit technology and, more particularly, to a semiconductor device and a method of operating a semiconductor device.

### Related Art

As the degree of integration of semiconductor devices increases, it becomes increasingly difficult to secure a stable operating characteristic of the transistors therein. In particular, characteristics of the transistor that need to be secured, such as a threshold voltage, a current driving ability, and an operating speed, approach a ceiling because a gate line width is sharply reduced and the size of the transistor is also decreased due to a fine process.

Accordingly, a semiconductor device that needs to perform a refresh operation every set time in order to retain data stored in the semiconductor device is being developed to increase the number of memory cells that are refreshed after the start of one refresh operation in order to reduce frequency of the refresh operation.

However, in these semiconductor devices, power noise that occurs because a large number of memory cells are refreshed at a time is also increased. Such power noise may cause a malfunction of the semiconductor device.

### SUMMARY

In accordance with an embodiment of the present disclosure, a semiconductor device may include a refresh control circuit configured to generate a refresh address during a refresh operation, and a row decoder configured to decode a row address during a normal operation and decode the refresh address, which has the number of bits different from the number of bits of the row address, during the refresh operation.

In accordance with an embodiment of the present disclosure, a semiconductor device may include a row decoder configured to decode a row address during a normal operation and decode a refresh address during a refresh operation, and a refresh control circuit configured to generate, during the refresh operation, the refresh address. The refresh address includes a smaller number of bits than a number of bits of the row address.

In accordance with an embodiment of the present disclosure, a method of operating a semiconductor device may include generating a refresh address during a refresh operation, decoding a row address during a normal operation, and decoding the refresh address during the refresh operation. The refresh address comprises a smaller number of bits than a number of bits of the row address.

### BRIEF DESCRIPTION OF THE DRAWINGS

FIG. 1 is a diagram illustrating a configuration of a semiconductor device according to an embodiment of the present disclosure.

FIG. 2 is a diagram illustrating a detailed configuration of a refresh control circuit of FIG. 1, according to an embodiment of the present disclosure.

FIGS. 3 and 4 are timing diagrams for describing operations of the semiconductor device according to an embodiment of the present disclosure.

Other features, aspects and advantages of the present invention will become clear in view of the following description and accompanying the drawings.

### DETAILED DESCRIPTION

Hereinafter, embodiments according to the technical spirit of the present disclosure are described with reference to the accompanying drawings.

Various embodiments are described below in more detail with reference to the accompanying drawings. The present disclosure may, however, be embodied in different forms and should not be construed as limited to the embodiments set forth herein. Rather, these embodiments are provided so that this disclosure is thorough and complete and fully conveys the scope of the present disclosure to those skilled in the art. Moreover, reference herein to “an embodiment,” “another embodiment,” or the like is not necessarily to only one embodiment, and different references to any such phrases is not necessarily to the same embodiment(s). Throughout the disclosure, like reference numerals refer to like parts in the figures and embodiments of the present disclosure.

Embodiments of the present disclosure relate to a technology for reducing power noise that occurs after the start of a refresh operation.

In accordance with embodiments of the present disclosure, a semiconductor device can secure high operation stability by reducing power noise.

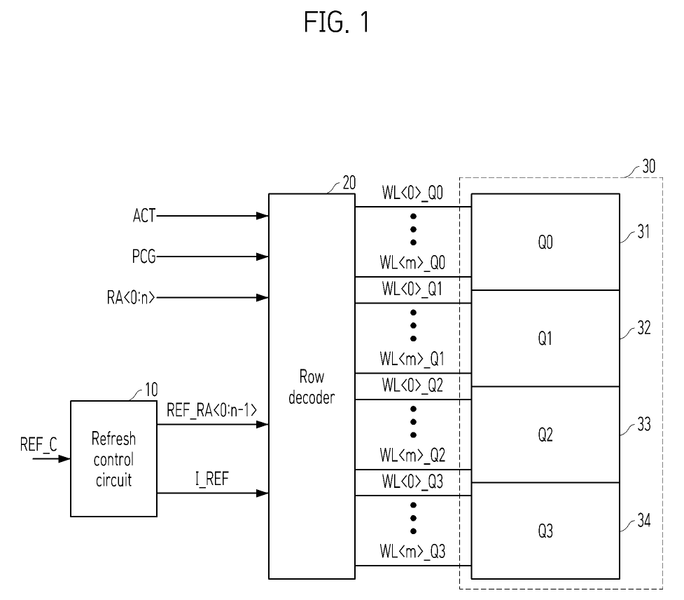

FIG. 1 is a diagram illustrating a configuration of a semiconductor device according to an embodiment of the present disclosure.

Referring to FIG. 1, the semiconductor device may include a refresh control circuit 10, a row decoder 20, and a bank (i.e., a memory bank) 30.

The refresh control circuit 10 may receive a refresh command signal REF_C. When receiving the refresh command signal REF_C, the refresh control circuit 10 may generate an internal refresh signal I_REF and a row address for refresh (i.e., a refresh address) REF_RA<0:n-1>. For example, when receiving the refresh command signal REF_C, the refresh control circuit 10 may generate the internal refresh signal I_REF that is activated for a predetermined time. Furthermore, whenever the internal refresh signal I_REF is activated, the refresh control circuit 10 may generate the row address for refresh REF_RA<0:n-1> having an increased address value. In this instance, the refresh command signal REF_C may be a signal that is periodically generated by a refresh command received from the outside of the semiconductor device or may be a signal that is periodically generated internally.

The row decoder 20 may enable one of a plurality of word lines WL<0>_Q0 to WL<m>_Q0, a plurality of word lines WL<0>_Q1 to WL<m>_Q1, a plurality of word lines WL<0>_Q2 to WL<m>_Q2, and a plurality of word lines WL<0>_Q3 to WL<m>_Q3, based on an active signal ACT, a precharge signal PCG, a row address (i.e., a row address for a normal operation) RA<0:n>, the internal refresh signal I_REF, and the row address for refresh REF_RA<0:n-1>. In this instance, the active signal ACT, the precharge signal PCG, and the row address RA<0:n> may each be a signal generated by a signal that is received from the outside of the semiconductor device.

For example, the row decoder 20 may select one word line to be activated by decoding the row address RA_<0:n>. The row decoder 20 may enable the selected one word line in response to the active signal ACT, and may deactivate (or precharge) the activated word line in response to the precharge signal PCG.

The row decoder 20 may select at least one word line to be activated by decoding the row address for refresh REF_RA<0:n-1>. When receiving the internal refresh signal I_REF, the row decoder 20 may enable the selected at least one word line for a predetermined time. In this instance, the number of word lines that is selected by decoding the row address for refresh REF_RA<0:n-1> may be different from the number of word lines that is selected by decoding the row address RA<0:n>. The number of word lines that is selected by decoding the row address for refresh REF_RA<0:n-1> may be greater than the number of word lines that is selected by decoding the row address RA<0:n>. The number of word lines that is selected by decoding the row address for refresh REF_RA<0:n-1> may be twice the number of word lines that is selected by decoding the row address RA<0:n> because the row address for refresh REF_RA<0:n-1> includes an address value that is one bit less than the address value of the row address RA<0:n>. More specifically, for example, assuming that there is a row decoder that selects eight word lines and n is 2, the row address RA<0:2> may have eight decoding values 000, 001, 010, 011, 100, 101, 110, and 111. One decoding value may correspond to one word line because eight word lines need to be selected based on the eight decoding values. One decoding value may correspond to two word lines because the row address for refresh REF_RA<0:1> may have four decoding values 00, 01, 10, and 11 and eight word lines need to be selected as the four decoding values. The number of address bits included in the row address for refresh REF_RA<0:n-1> may be smaller than the number of address bits included in the row address RA<0:n>. For example, the row address for refresh REF_RA<0:n-1> may include the address bit REF_RA<n> less than the row address RA<0:n>. The address bit REF_RA<n-1> included in the row address for refresh REF_RA<0:n-1> may be the lowest row address bit for refresh.

The bank 30 may include first to fourth quarter banks Q0 31, Q1 32, Q2 33, and Q3 34. In this instance, one bank may include a plurality of quarter banks. FIG. 1 illustrates an embodiment in which one bank 30 includes the four quarter banks Q0, Q1, Q2, and Q3. Furthermore, the plurality of word lines WL<0>_Q0 to WL<m>_Q0, the plurality of word lines WL<0>_Q1 to WL<m>_Q1, the plurality of word lines WL<0>_Q2 to WL<m>_Q2, and the plurality of word lines WL<0>_Q3 to WL<m>_Q3 may include a first group of word lines WL<0>_Q0 to WL<m>_Q0, a second group of word lines WL<0>_Q1 to WL<m>_Q1, a third group of word lines WL<0>_Q2 to WL<m>_Q2, and a fourth group of word lines WL<0>_Q3 to WL<m>_Q3, respectively. Each of the first to fourth groups of word lines WL<0>_Q0 to WL<m>_Q0, WL<0>_Q1 to WL<m>_Q1, WL<0>_Q2 to WL<m>_Q2, and WL<0>_Q3 to WL<m>_Q3 may include a plurality of word lines.

The first quarter bank Q0 may include a plurality of memory cells that are connected to the first group of word lines WL<0>_Q0 to WL<m>_Q0.

The second quarter bank Q1 may include a plurality of memory cells that are connected to the second group of word lines WL<0>_Q1 to WL<m>_Q1.

The third quarter bank Q2 may include a plurality of memory cells that are connected to the third group of word lines WL<0>_Q2 to WL<m>_Q2.

The fourth quarter bank Q3 may include a plurality of memory cells that are connected to the fourth group of word lines WL<0>_Q3 to WL<m>_Q3.

In this instance, the plurality of memory cells included in each of the first to fourth quarter banks Q0, Q1, Q2, and Q3 may store data by receiving the data through a plurality of bit lines (not illustrated), and may transmit the stored data. For example, one memory cell may be electrically connected between a word line and a bit line. When the word line is activated, the memory cell may be electrically connected to the bit line. When the word line is deactivated, the memory cell may be electrically separated from the bit line. The semiconductor device according to an embodiment of the present disclosure is related to a word line operation, and thus a description of the bit line is omitted.

The word lines of each of the first to fourth groups of word lines WL<0>_Q0 to WL<m>_Q0, WL<0>_Q1 to WL<m>_Q1, WL<0>_Q2 to WL<m>_Q2, and WL<0>_Q3 to WL<m>_Q3 connected to the memory cells of the bank 30 may be selectively activated by the row decoder 20.

For example, a word line that is selected by the row decoder 20 as the row address RA<0:n> is decoded by the row decoder 20 after the start of a normal operation may be one word line, among a group of word lines selected in the first group of word lines WL<0>_Q0 to WL<m>_Q0, the second group of word lines WL<0>_Q1 to WL<m>_Q1, the third group of word lines WL<0>_Q2 to WL<m>_Q2, and the fourth group of word lines WL<0>_Q3 to WL<m>_Q3. That is, one quarter bank, among the first to fourth quarter banks Q0, Q1, Q2, and Q3, may include one word line that is activated as the row address RA<0:n> is decoded by the row decoder 20. Furthermore, after the start of a refresh operation, each of some quarter banks, among the first to fourth quarter banks Q0, Q1, Q2, and Q3, may include one word line that is activated as the row address for refresh REF_RA<0:n-1> is decoded by the row decoder 20.

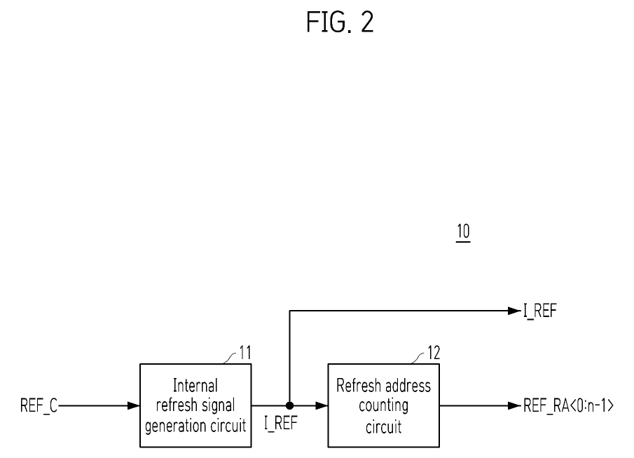

FIG. 2 is a diagram illustrating a detailed configuration of the refresh control circuit of FIG. 1, according to an embodiment of the present disclosure.

Referring to FIG. 2, the refresh control circuit 10 may include an internal refresh signal generation circuit 11 and a refresh address counting circuit 12.

The internal refresh signal generation circuit 11 may generate the internal refresh signal I_REF whenever the refresh command signal REF_C is received. In this instance, the internal refresh signal I_REF may have a pulse form, and may be activated for a predetermined time. The internal refresh signal generation circuit 11 may include a pulse generation circuit.

The refresh address counting circuit 12 may increase the address value of the row address for refresh REF_RA<0:n-1> whenever the internal refresh signal I_REF is activated. For example, the refresh address counting circuit 12 may increase the address value of the row address for refresh REF_RA<0:n-1> by +1 whenever the internal refresh signal I_REF is activated. The refresh address counting circuit 12 may include a counting circuit, e.g., a counter.

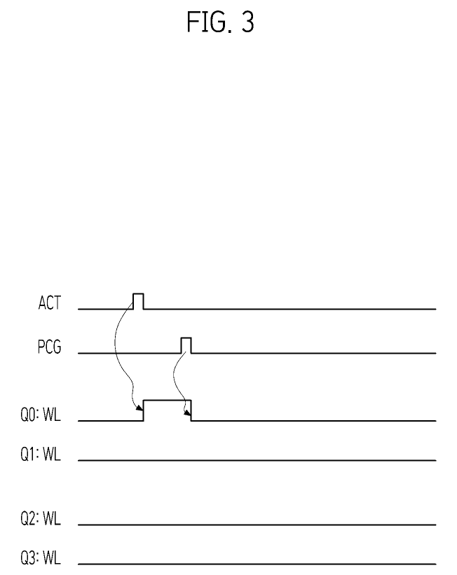

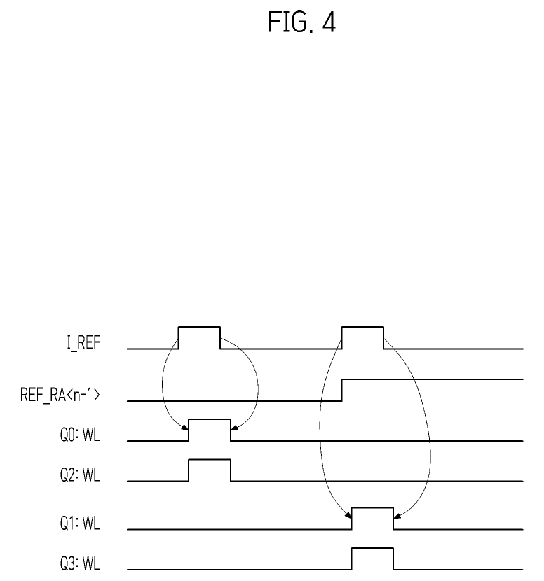

FIGS. 3 and 4 are timing diagrams for describing operation of the semiconductor device according to an embodiment of the present disclosure. In this instance, FIGS. 3 and 4 are merely embodiments for describing operations of the semiconductor device, but do not limit operations of the semiconductor device according to an embodiment of the present disclosure.

FIG. 3 illustrates a timing diagram of an operation of enabling, by the semiconductor device according to an embodiment of the present disclosure, word lines by the row address RA<0:n> after the start of a normal operation.

After the start of a normal operation, the semiconductor device may enable one of a plurality of word lines by receiving the active signal ACT and the row address RA<0:n> from the outside of the semiconductor device. In response to the precharge signal PCG that is received from the outside of the semiconductor device, the semiconductor device may deactivate a word line that is activated after the start of a normal operation.

Referring to FIG. 3, the row decoder 20 may select one group word line, among the first group of word lines WL<0>_Q0 to WL<m>_Q0, the second group of word lines WL<0>_Q1 to WL<m>_Q1, the third group of word lines WL<0>_Q2 to WL<m>_Q2, and the fourth group of word lines WL<0>_Q3 to WL<m>_Q3 by decoding the row address RA<0:n>, and may select one word line included in the selected group word line. In this instance, FIG. 3 illustrates that the first group of word lines WL<0>_Q0 to WL<m>_Q0 is selected by decoding the row address RA<0:n> after the start of a normal operation and one word line included in the selected group word line WL<0>_Q0 to WL<m>_Q0 is activated. In this instance, the selected one word line is illustrated as (Q0: WL) because the first group of word lines WL<0>_Q0 to WL<m>_Q0 includes word lines that are connected to the memory cells of the first quarter bank Q0. The second group of word lines WL<0>_Q1 to WL<m>_Q1 includes word lines that are connected to the memory cells of the second quarter bank Q1. Accordingly, when the second group of word lines WL<0>_Q1 to WL<m>_Q1 is selected, one word line that will be selected in the second group of word lines WL<0>_Q1 to WL<m>_Q1 will be illustrated as (Q1: WL). The third group of word lines WL<0>_Q2 to WL<m>_Q2 includes word lines that are connected to the memory cells of the third quarter bank Q2. Accordingly, when the third group of word lines WL<0>_Q2 to WL<m>_Q2 is selected, one word line that will be selected in the third group of word lines WL<0>_Q2 to WL<m>_Q2 will be illustrated as (Q2: WL). The fourth group of word lines WL<0>_Q3 to WL<m>_Q3 includes word lines that are connected to the memory cells of the fourth quarter bank Q3. Accordingly, when the fourth group of word lines WL<0>_Q3 to WL<m>_Q3 is selected, one word line that will be selected in the fourth group of word lines WL<0>_Q3 to WL<m>_Q3 will be illustrated as (Q3: WL).

When receiving the active signal ACT, the row decoder 20 may enable one word line (Q0: WL) selected in the first group of word lines WL<0>_Q0 to WL<m>_Q0.

When receiving the precharge signal PCG, the row decoder 20 may deactivate the one word line (Q0: WL) activated in the first group of word lines WL<0>_Q0 to WL<m>_Q0.

After the start of a normal operation, while one word line selected in a group of word lines selected among the first to fourth group of word lines WL<0>_Q0 to WL<m>_Q0, WL<0>_Q1 to WL<m>_Q1, WL<0>_Q2 to WL<m>_Q2, and WL<0>_Q3 to WL<m>_Q3, is activated, data may be stored in a memory cell (not illustrated) through a bit line (not illustrated) or data stored in the memory cell may be output from the memory cell through the bit line.

FIG. 4 illustrates a timing diagram of an operation of enabling, by the semiconductor device according to an embodiment of the present disclosure, word lines by the row address for refresh REF_RA<0:n-1>.

FIG. 4 illustrates a timing diagram of an operation of enabling word lines by the internal refresh signal I_REF and the row address for refresh REF_RA<0:n-1> that are generated within the semiconductor device after the start of a refresh operation.

Referring to FIG. 4, when the lowest row address for refresh REF_RA<n-1> is at a low level as a result of decoding the row address for refresh REF_RA<0:n-1>, the row decoder 20 may select one word line in the first group of word lines WL<0>_Q0 to WL<m>_Q0 and one word line in the third group of word lines WL<0>_Q2 to WL<m>_Q2. Furthermore, when the lowest row address for refresh REF_RA<n-1> is at a high level as the results of decoding the row address for refresh REF_RA<0:n-1>, the row decoder 20 may select one word line in the second group of word lines WL<0>_Q1 to WL<m>_Q1 and one word line in the fourth group of word lines WL<0>_Q3 to WL<m>_Q3. In this instance, in FIG. 4, one word line selected in the first group of word lines WL<0>_Q0 to WL<m>_Q0 is illustrated as (Q0: WL) because the first group of word lines WL<0>_Q0 to WL<m>_Q0 includes word lines that are connected to the memory cells of the first quarter bank Q0. One word line selected in the second group of word lines WL<0>_Q1 to WL<m>_Q1 is illustrated as (Q1: WL) because the second group of word lines WL<0>_Q1 to WL<m>_Q1 includes word lines that are connected to the memory cells of the second quarter bank Q1. One word line selected in the third group of word lines WL<0>_Q2 to WL<m>_Q2 is illustrated as (Q2: WL) because the third group of word lines WL<0>_Q2 to WL<m>_Q2 includes word lines that are connected to the memory cells of the third quarter bank Q2. One word line selected in the fourth group of word lines WL<0>_Q3 to WL<m>_Q3 is illustrated as (Q3: WL) because the fourth group of word lines WL<0>_Q3 to WL<m>_Q3 includes word lines that are connected to the memory cells of the fourth quarter bank Q3.

During the time period (or at the time) at which the internal refresh signal I_REF is activated for the first time, that is, at the first rising timing, the row decoder 20 may enable one word line (Q0: WL) selected in the first group of word lines WL<0>_Q0 to WL<m>_Q0 and one word line (Q2: WL) selected in the third group of word lines WL<0>_Q2 to WL<m>_Q2. During the time period at which the internal refresh signal I_REF is activated for the first time, the lowest row address for refresh REF_RA<n-1> may be at a low level.

During the time period at which the internal refresh signal I_REF is deactivated for the first time, that is, at the first falling timing, the row decoder 20 may deactivate the one word line (Q0: WL) activated in the first group of word lines WL<0>_Q0 to WL<m>_Q0 and the one word line (Q2: WL) activated in the third group of word lines WL<0>_Q2 to WL<m>_Q2.

Thereafter, during the time period at which the internal refresh signal I_REF is activated for the second time, that is, at the second rising timing, the row decoder 20 may enable one word line (Q1: WL) selected in the second group of word lines WL<0>_Q1 to WL<m>_Q1 and one word line (Q3: WL) selected in the fourth group of word lines WL<0>_Q3 to WL<m>_Q3. During the time period at which the internal refresh signal I_REF is activated for the second time, the lowest row address for refresh REF_RA<n+1> may be at a high level.

During the time period at which the internal refresh signal I_REF is deactivated for the second time, that is, at the second falling timing, the row decoder 20 may deactivated the one word line (Q1: WL) activated in the second group of word lines WL<0>_Q1 to WL<m>_Q1 and the one word line (Q3: WL) activated in the fourth group of word lines WL<0>_Q3 to WL<m>_Q3.

The semiconductor device according to an embodiment of the present disclosure can reduce power noise after the start of a refresh operation because the semiconductor device is configured to minimize the number of word lines that is simultaneously activated by decoding the row address for refresh, including a smaller number of bits than the row address, after the start of a refresh operation within one bank.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a refresh control circuit configured to generate a refresh address during a refresh operation; and
a row decoder configured to
decode a row address during a normal operation, and
decode the refresh address, which has a number of bits different from a number of bits of the row address, during the refresh operation.

2. The semiconductor device of claim 1, wherein the row decoder is configured to receive the refresh address which comprises a smaller number of bits than the number of bits of the row address.

3. The semiconductor device of claim 1, wherein the number of bits of the refresh address is one less than the row address.

4. The semiconductor device of claim 3, wherein the refresh address does not include a bit corresponding to a lowest bit of the row address.

5. The semiconductor device of claim 4, wherein a number of word lines selected by the row decoder by decoding the refresh address during the refresh operation is twice a number of word lines selected by the row decoder by decoding the row address during the normal operation.

6. The semiconductor device of claim 1, wherein when receiving a refresh command signal, the refresh control circuit is configured to:
generate an internal refresh signal; and
increase an address value of the refresh address whenever the internal refresh signal is generated.

7. The semiconductor device of claim 1, further comprising:
a first quarter bank comprising a plurality of memory cells electrically connected to a first group of word lines;
a second quarter bank comprising a plurality of memory cells electrically connected a second group of word lines;
a third quarter bank comprising a plurality of memory cells electrically connected to a third group of word lines; and
a fourth quarter bank comprising a plurality of memory cells electrically connected to a fourth group of word lines,
wherein the first to fourth quarter banks forms one bank.

8. The semiconductor device of claim 7, wherein the row decoder is configured to:
select a group of word lines, among the first to fourth groups of word lines, and activate one word line included in the selected group of word lines during the normal operation; and
activate one word line included in each of some groups of word lines, among the first to fourth groups of word lines, during the refresh operation.

9. The semiconductor device of claim 8, wherein:
the refresh address comprises one less address bit than the row address,
the address bit that is one less included in the refresh address is a lowest bit of the row address, and
the row decoder is configured to:
activate one word line included in each of the first and third groups of word lines when a lowest bit of the refresh address is at a first level; and
activate one word line included in each of the second and fourth groups of word lines when the lowest bit of the refresh address is at a second level during the refresh operation.

10. A semiconductor device comprising:
a row decoder configured to
decode a row address during a normal operation, and
decode a refresh address during a refresh operation; and
a refresh control circuit configured to generate, during the refresh operation, the refresh address,
wherein the refresh address comprises a smaller number of bits than a number of bits of the row address.

11. The semiconductor device of claim 10, wherein:
the refresh address comprises one less bit than the row address; and
the refresh address does not include a bit corresponding to a lowest bit of the row address.

12. The semiconductor device of claim 11, wherein the row decoder is configured to:
select one word line, among a plurality of word lines, by decoding the row address during the normal operation, and
select two word lines, among the plurality of word lines, by decoding the refresh address during the refresh operation.

13. The semiconductor device of claim 12, further comprising:
a first quarter bank comprising a plurality of memory cells electrically connected to a first group of word lines of the plurality of word lines;
a second quarter bank comprising a plurality of memory cells electrically connected a second group of word lines of the plurality of word lines;
a third quarter bank comprising a plurality of memory cells electrically connected to a third group of word lines of the plurality of word lines; and
a fourth quarter bank comprising a plurality of memory cells electrically connected to a fourth group of word lines of the plurality of word lines,
wherein the first to fourth quarter banks forms one bank.

14. The semiconductor device of claim 13, wherein the row decoder is configured to:
activate one word line included in a group of word lines, among the first to fourth groups of word lines, by decoding the row address during the normal operation, and
activate one word line included in each of two groups of word lines, among the first to fourth groups of word lines, by decoding the refresh address during the refresh operation.

15. The semiconductor device of claim 14, wherein, during the refresh operation, the row decoder is configured to:
activate one word line included in each of the first and third groups of word lines when a lowest bit of the refresh address is at a first level; and
activate one word line included in each of the second and fourth groups of word lines when the lowest bit of the refresh address is at a second level .

16. A method of operating a semiconductor device, the method comprising:
generating a refresh address during a refresh operation;
decoding a row address during a normal operation; and
decoding the refresh address during the refresh operation,
wherein the refresh address comprises a smaller number of bits than a number of bits of the row address.
